(19) United States
(12) Patent Application Publication
(10) Pub. No.: US 2017/0162595 A1
(43) Pub. Date: Jun. 8, 2017

(54) SEMICONDUCTOR DEVICE AND METHOD FOR MANUFACTURING THE SAME

(71) Applicant: Kabushiki Kaisha Toshiba, Minato-ku (JP)

(72) Inventor: Yoshiyuki KITAHARA, Fujisawa (JP)

(73) Assignee: Kabushiki Kaisha Toshiba, Minato-ku (JP)

(21) Appl. No.: 15/357,167

(22) Filed: Nov. 21, 2016

(30) Foreign Application Priority Data
Dec. 8, 2015 (JP) 2015-239411

(51) Int. Cl. H01L 27/115; H01L 21/3213; H01L 21/311

(52) U.S. Cl. CPC H01L 27/11582; H01L 21/31144; H01L 21/32139

(57) ABSTRACT

According to one embodiment, a semiconductor device includes a stacked body, a memory cell array, and a columnar portion. The stacked body is provided on a major surface of a substrate. The stacked body includes a plurality of electrode layers stacked with an insulating body interposed. The memory cell array is provided inside the stacked body. The columnar portion is provided inside the memory cell array. The columnar portion extends along a stacking direction of the stacked body. The columnar portion includes a semiconductor body and a memory film. The memory film includes a charge storage portion. The substrate includes a first contact portion contacting the semiconductor body. A configuration of the first contact portion is convex along the stacking direction.

### CROSS-REFERENCE TO RELATED APPLICATIONS

This application is based upon and claims the benefit of priority from Japanese Patent Application No. 2015-239411, filed on Dec. 8, 2015; the entire contents of which are incorporated herein by reference.

### FIELD

Embodiments described herein relate generally to a semiconductor device and a method for manufacturing the same.

### BACKGROUND

A memory device having a three-dimensional structure has been proposed in which memory holes are formed in a stacked body in which multiple electrode layers are stacked, and a charge storage film and a semiconductor film are provided to extend in the stacking direction of the stacked body inside the memory hole. The memory hole is an opening; and the aspect ratio of the memory hole is large. Therefore, it is difficult to perpendicularly pattern the memory hole to the lower layers. The diameter of the memory hole is small at the lower layers and large at the upper layers. The resistance value of the word line is low at the lower layers and high at the upper layers. For example, the difference between the resistance values of the word lines causes the charge/discharge characteristics of the word lines to fluctuate. For example, the fluctuation of the charge/discharge characteristics of the word lines causes misprogramming such as program disturbance, read disturbance, etc. It is desirable for the sidewall of the opening to approach perpendicular.

### BRIEF DESCRIPTION OF THE DRAWINGS

FIG. 1 is a schematic plan view showing a planar layout of a semiconductor device of an embodiment;

FIG. 2 is a schematic perspective view of a memory cell array of the semiconductor device of the embodiment;

FIG. 3 is a schematic plan view of the memory cell array and a staircase portion of the semiconductor device of the embodiment;

FIG. 4 is a schematic cross-sectional view along line 4-4 in FIG. 3;

FIG. 5 is a schematic cross-sectional view along line 5-5 in FIG. 3;

FIG. 6 is a schematic cross-sectional view of a columnar portion of the semiconductor device of the embodiment;

FIG. 7 is a schematic cross-sectional view of a post of the semiconductor device of the embodiment;

FIG. 8 is a schematic cross-sectional view of a gate contact portion of the semiconductor device of the embodiment;

FIG. 9 is a schematic cross-sectional view of a source line of the semiconductor device of the embodiment;

FIG. 10 to FIG. 18 are schematic cross-sectional views showing a method for manufacturing the semiconductor device of the embodiment;

FIG. 19 is a schematic plan view of a hole pattern;

FIG. 20 is a schematic plan view of a space pattern;

FIG. 21 is a schematic cross-sectional view showing a state of the anisotropic etching; and

FIG. 22 is a schematic plan view showing an arrangement of hole patterns.

### DETAILED DESCRIPTION

According to one embodiment, a semiconductor device includes a stacked body, a memory cell array, and a columnar portion. The stacked body is provided on a major surface of a substrate. The stacked body includes a plurality of electrode layers stacked with an insulating body interposed. The memory cell array is provided inside the stacked body. The columnar portion is provided inside the memory cell array. The columnar portion extends along a stacking direction of the stacked body. The columnar portion includes a semiconductor body and a memory film. The memory film includes a charge storage portion. The substrate includes a first contact portion contacting the semiconductor body. A configuration of the first contact portion is convex along the stacking direction.

Embodiments will now be described with reference to the drawings. In the respective drawings, like members are labeled with like reference numerals. Semiconductor devices of the embodiments are semiconductor memory devices having memory cell arrays.

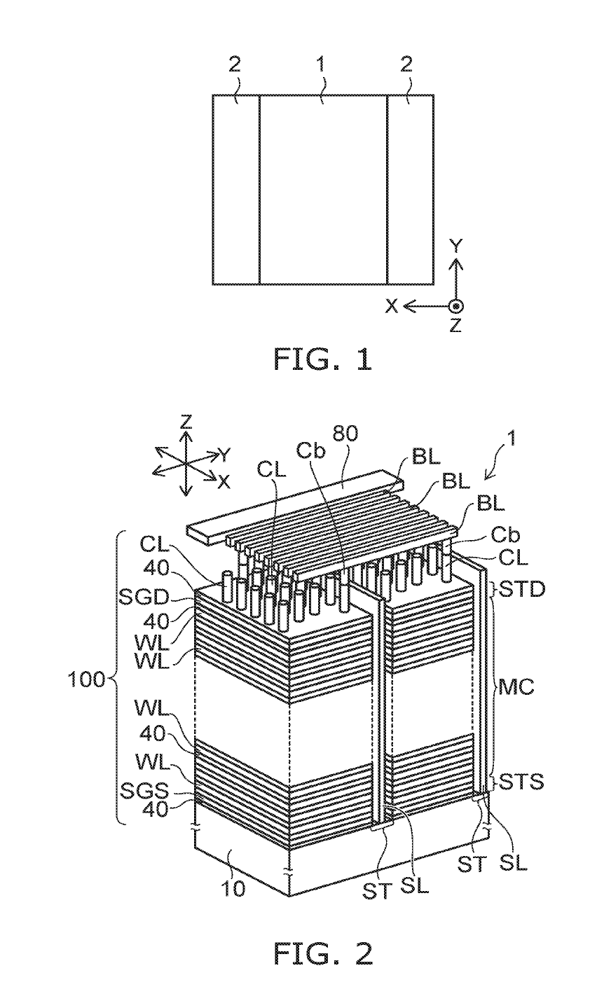

FIG. 1 is a schematic plan view showing a planar layout of a semiconductor device of an embodiment.

The semiconductor device includes a memory cell array 1 and a staircase portion 2. The memory cell array 1 and the staircase portion 2 are provided on the substrate. The staircase portion 2 is provided on the outer side of the memory cell array 1. In FIG. 1, two mutually-orthogonal directions parallel to a major surface of the substrate are taken as an X-direction and a Y-direction; and a direction orthogonal to both the X-direction and the Y-direction is taken as a Z-direction (a stacking direction).

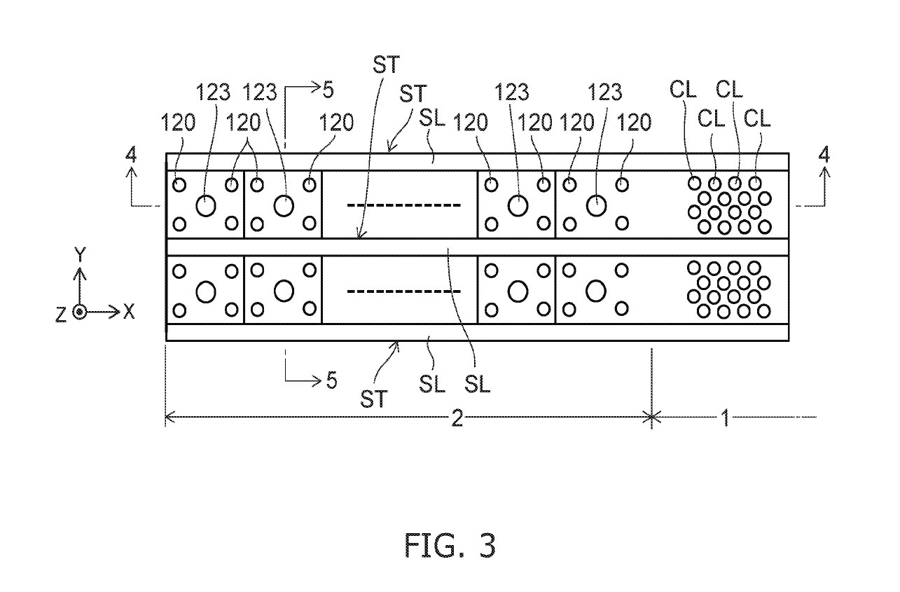

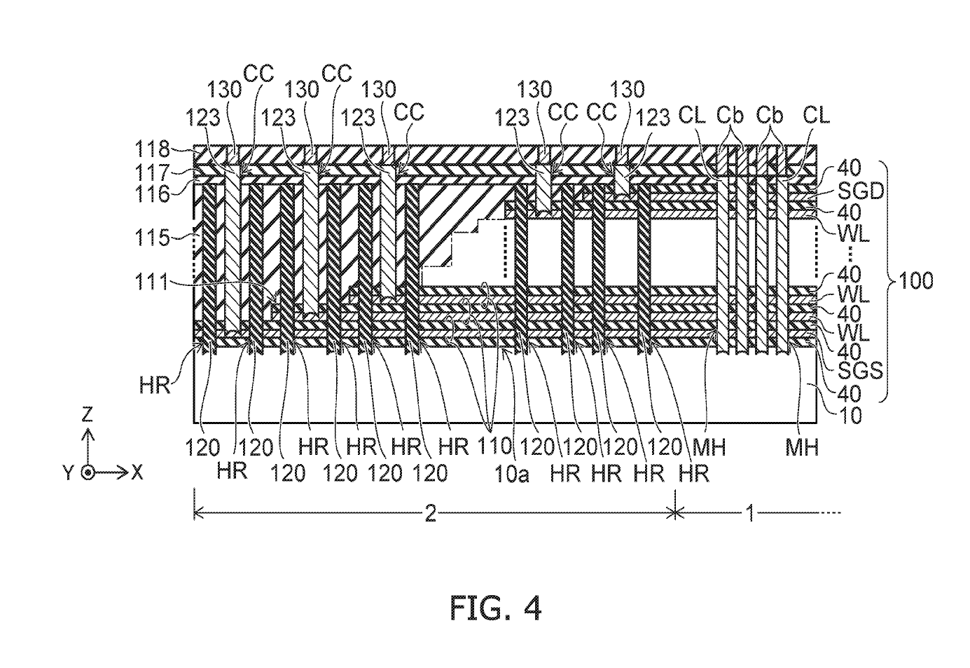

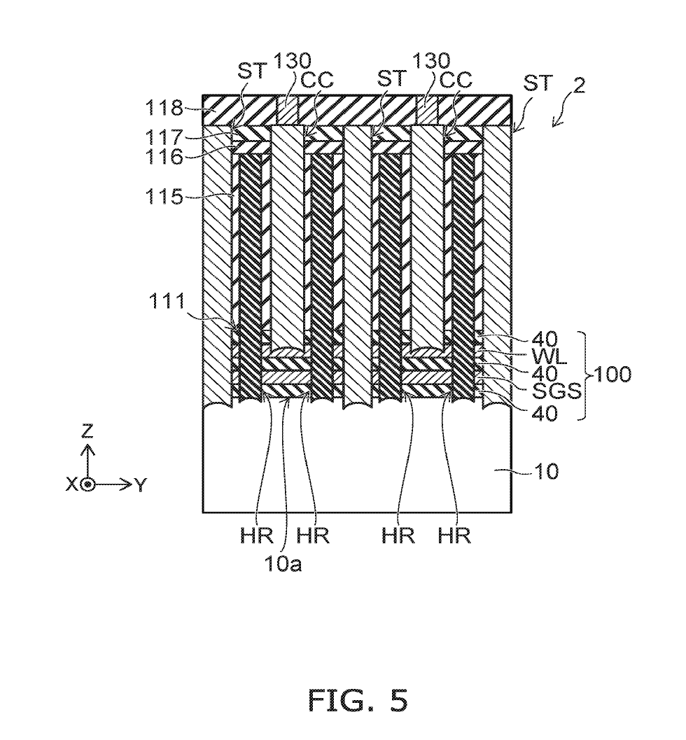

FIG. 2 is a schematic perspective view of the memory cell array 1 of the semiconductor device of the embodiment. FIG. 3 is a schematic plan view of the memory cell array 1 and the staircase portion 2 of the semiconductor device of the embodiment. FIG. 4 is a schematic cross-sectional view along line 4-4 in FIG. 3. FIG. 5 is a schematic cross-sectional view along line 5-5 in FIG. 3.

As shown in FIG. 3 to FIG. 5, the memory cell array 1 includes a stacked body 100, multiple columnar portions CL, and multiple slits ST. The stacked body 100 includes a drain-side selection gate SGD, multiple word lines WL, and a source-side selection gate SGS.

The source-side selection gate SGS is provided on a major surface 10a of a substrate 10. The substrate 10 is, for example, a semiconductor substrate. The semiconductor substrate includes, for example, silicon. The multiple word lines WL are provided on the source-side selection gate SGS. The drain-side selection gate SGD is provided on the multiple word lines WL. The drain-side selection gate SGD, the multiple word lines WL, and the source-side selection gate SGS are electrode layers. The number of stacks of electrode layers is arbitrary.

The electrode layers (SGD, WL, and SGS) are stacked to be separated. Insulating bodies 40 are disposed between the electrode layers (SGD, WL, and SGS). The insulating bodies 40 may be insulators such as silicon oxide films, etc., or may be air gaps.

At least one selection gate SGD is used as a gate electrode of a drain-side selection transistor STD. At least one selection gate SGS is used as a gate electrode of a source-side selection transistor STS. Multiple memory cells MC are connected in series between the drain-side selection transistor STD and the source-side selection transistor STS. One of the word lines WL is used as a gate electrode of the memory cell MC.

The slits ST are provided inside the stacked body 100. The slits ST extend in the Z-direction (the stacking direction) and the X-direction through the stacked body 100. The slits ST divide the stacked body 100 into a plurality in the Y-direction. The regions that are divided by the slits ST are called “blocks.”

The columnar portions CL are provided inside the stacked body 100 divided by the slits ST. The columnar portions CL extend in the Z-direction (the stacking direction). For example, the columnar portions CL are formed in circular columnar configurations or elliptical columnar configurations. For example, the columnar portions CL are disposed in a staggered lattice configuration or a square lattice configuration inside the memory cell array 1. The drain-side selection transistor STD, the multiple memory cells MC, and the source-side selection transistor STS are disposed in the columnar portions CL.

Multiple bit lines BL are disposed above the upper end portions of the columnar portions CL. The multiple bit lines BL extend in the Y-direction. The upper end portion of the columnar portion CL is electrically connected to one of the bit lines BL via a contact portion Cb. One bit line BL is electrically connected to one columnar portion CL selected from each block.

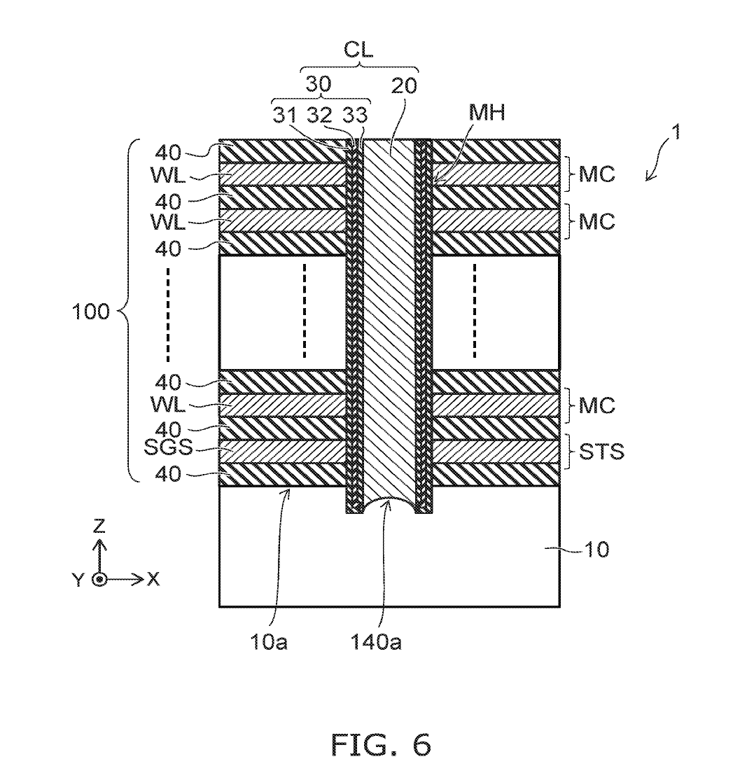

FIG. 6 is a schematic cross-sectional view of the columnar portion CL of the semiconductor device of the embodiment. For example, FIG. 6 corresponds to the cross section shown in FIG. 4. FIG. 6 extracts and illustrates a middle portion and a portion of the lower layers of the columnar portion CL. The memory cells MC and the source-side selection transistor STS are shown in FIG. 6.

The columnar portion CL is provided inside a memory hole (an opening) MH. The memory hole MH is provided inside the stacked body 100. The configuration of the columnar portion CL is, for example, a columnar configuration having a concave bottom surface. The columnar portion CL includes a memory film 30 and a semiconductor body 20.

The memory film 30 is provided on the inner wall of the memory hole MH. The configuration of the memory film 30 is, for example, a tubular configuration. The memory film 30 includes a cover insulating film 31, a charge storage film 32, and a tunneling insulating film 33.

The cover insulating film 31 is provided on the inner wall of the memory hole MH. For example, the cover insulating film 31 includes silicon oxide, or includes silicon oxide and aluminum oxide. For example, the cover insulating film 31 protects the charge storage film 32 from the etching when forming the electrode layers (SGD, WL, and SGS).

The charge storage film 32 is provided on the cover insulating film 31. The charge storage film 32 includes, for example, silicon nitride. Other than silicon nitride, the charge storage film 32 may include hafnium oxide. The charge storage film 32 traps charge by having trap sites that trap the charge inside a film. The threshold of the memory cell MC changes due to the existence or absence of the trapped charge and the amount of the trapped charge. Thereby, the memory cell MC stores information.

The tunneling insulating film 33 is provided on the charge storage film 32. For example, the tunneling insulating film 33 includes silicon oxide, or includes silicon oxide and silicon nitride. The tunneling insulating film 33 is a potential barrier between the charge storage film 32 and the semiconductor body 20. Tunneling of the charge occurs in the tunneling insulating film 33 when the charge is injected from the semiconductor body 20 into the charge storage film 32 (a program operation) and when the charge is diffused from the charge storage film 32 into the semiconductor body 20 (an erase operation). The electrode layers (SGD, WL, and SGS) surround the periphery of the columnar portion CL.

The semiconductor body 20 is provided on the memory film 30. The semiconductor body 20 includes, for example, silicon. The silicon is, for example, polysilicon made of amorphous silicon that is crystallized. The conductivity type of the silicon is, for example, a P-type. For example, the semiconductor body 20 is electrically connected to the substrate 10.

The staircase portion 2 includes the stacked body 100. The stacked body 100 includes multiple structure bodies 110 in the staircase portion 2. The staircase portion 2 is obtained by stacking the structure bodies 110 in a staircase configuration. The structure body 110 includes an electrode layer (SGD, WL, and SGS) and the insulating body 40. In the staircase portion 2, the portion where the upper surface of the structure body 110 is exposed is called a “terrace 111.” The portion where the side surface of the structure body 110 is exposed is called a “level difference 112.”

A first insulating film 115 is provided on the structure bodies 110. The first insulating film 115 includes, for example, silicon oxide. The first insulating film 115 is formed by providing the staircase portion 2 and by forming the first insulating film 115 on the stacked body 100 where the recess is formed in the staircase portion 2 by using, for example, a prescribed film formation method (e.g., CVD). After forming the first insulating film 115 on the stacked body 100, the first insulating film 115 is recessed so that the upper surface of the first insulating film 115 and the upper surface of the stacked body 100 substantially match each other. Thereby, the recess that is formed on the staircase portion 2 is filled with the first insulating film 115; and the front surface of the semiconductor device is planarized from the memory cell array 1 to the staircase portion 2. A second insulating film 116 is provided on the stacked body 100 and the first insulating film 115. A third insulating film 117 is provided on the second insulating film 116. A fourth insulating film 118 is provided on the third insulating film 117. The second to fourth insulating films 116 to 118 include, for example, silicon oxide.

Multiple holes HR are provided inside the first insulating film 115 and the structure bodies 110 in the staircase portion 2. For example, the holes HR reach the substrate 10 via the terraces 111. For example, the holes HR are provided respectively for the structure bodies 110. Posts 120 are provided. The electrode layers (SGD, WL, and SGS) are formed by replacing replacement members provided between the insulating body 40 and the insulating body 40 with a conductor. The replacement members include, for example, silicon nitride. The conductor includes, for example, tungsten. A space forms between the insulating body 40 and the insulating body 40 in the replace process. The posts 120 support the insulating bodies 40 in the replace process.

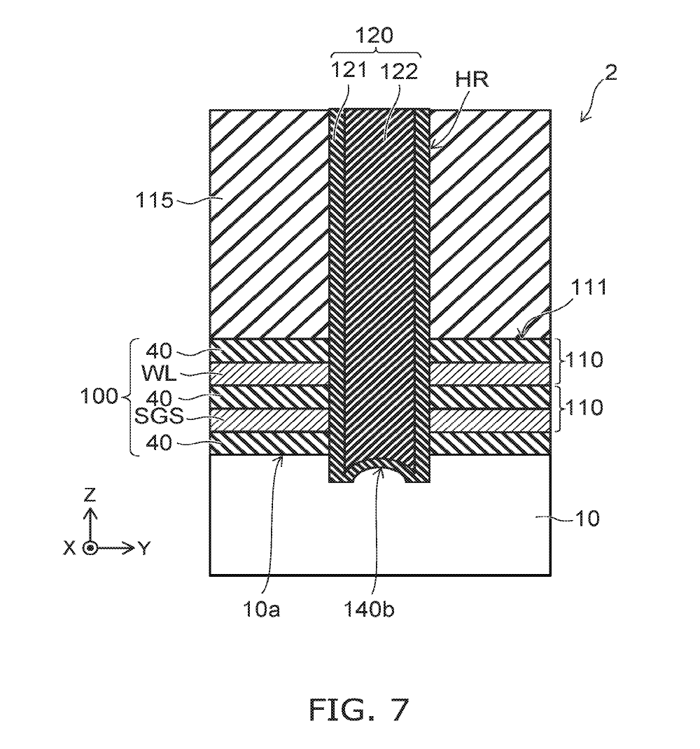

FIG. 7 is a schematic cross-sectional view of the post 120 of the semiconductor device of the embodiment. For example, FIG. 7 corresponds to the cross section shown in FIG. 5. FIG. 7 extracts and illustrates a middle portion and a portion of the lower layers of the post 120.

As shown in FIG. 7, the post 120 is an insulating body. The post 120 includes, for example, a silicon oxide film 121 and a silicon nitride film 122. For example, the silicon oxide film 121 is provided on the inner wall of the hole HR. The configuration of the silicon oxide film 121 is, for example, a tubular configuration having a bottom. The silicon nitride film 122 is provided on the silicon oxide film 121. The configuration of the post 120, e.g., the configuration of the silicon nitride film 122, is, for example, a columnar configuration having a concave bottom surface. The silicon oxide film 121 is a barrier for the etching in the replace process. By providing the silicon oxide film 121 on the inner wall of the hole HR, the silicon nitride film 122 is protected from the etching in the replace process.

In the staircase portion 2, multiple contact holes CC are provided in the first insulating film 115, the second insulating film 116, and the third insulating film 117. The contact holes CC reach the electrode layers (SGD, WL, and SGS) via the terraces 111. For example, the contact holes CC are provided respectively for the structure bodies 110. Gate contact portions 123 are provided inside the contact holes CC.

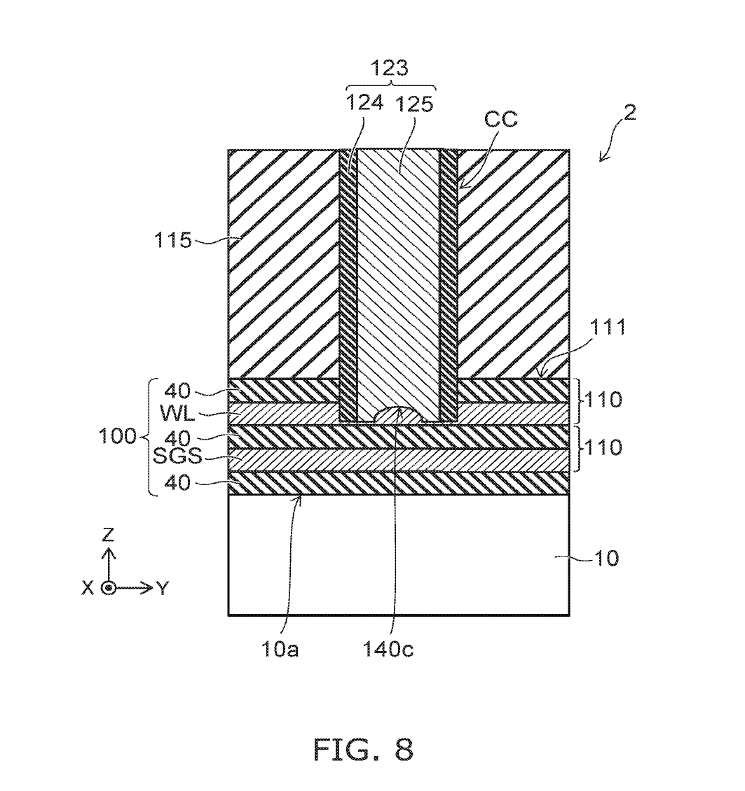

FIG. 8 is a schematic cross-sectional view of the gate contact portion 123 of the semiconductor device of the embodiment. For example, FIG. 8 corresponds to the cross section shown in FIG. 5. FIG. 8 extracts and illustrates a middle portion and a portion of the lower layers of the gate contact portion 123.

As shown in FIG. 8, the gate contact portion 123 includes a silicon oxide film 124 and a conductive body 125. For example, the silicon oxide film 124 is provided on the inner wall of the contact hole CC. The side surface of the conductive body 125 contacts the silicon oxide film 124. The configuration of the gate contact portion 123, e.g., the configuration of the conductive body 125, is, for example, a columnar configuration having a concave bottom surface. The conductive body 125 is, for example, tungsten. The conductive bodies 125 are electrically connected to the electrode layers (SGD, WL, and SGS) via the terraces 111. In FIG. 8, the conductive body 125 that is connected to the word line WL is shown.

In the memory cell array 1 and the staircase portion 2, the multiple slits ST are provided in the first insulating film 115, the second insulating film 116, and the third insulating film 117. The slits ST reach the substrate 10 via the terraces 111 and the stacked body 100. Plate portions are disposed inside the slits ST. The plate portions of the embodiment are source lines SL.

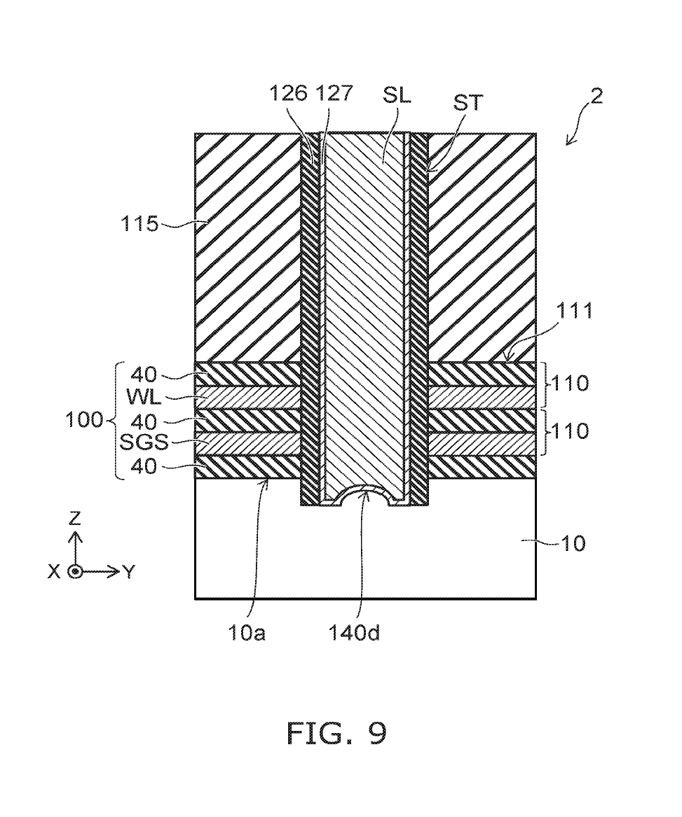

FIG. 9 is a schematic cross-sectional view of the source line SL of the semiconductor device of the embodiment. For example, FIG. 9 corresponds to the cross section shown in FIG. 5. FIG. 9 extracts and illustrates a middle portion and a portion of the lower layers of the source line SL.

As shown in FIG. 9, the source line SL includes a conductive body. The conductive body is, for example, tungsten. The source line SL is electrically insulated from the stacked body 100 via a sidewall insulating film 126. For example, the sidewall insulating film 126 is provided on the sidewall of the slit ST. The sidewall insulating film 126 includes, for example, silicon oxide. The source line SL is electrically connected to the substrate 10 via the bottom of the slit ST. The configuration of the plate portion, e.g., the configuration of the conductive body 125, is, for example, a plate configuration having a concave bottom surface and extending in the X-direction. For example, a barrier film 127 is provided between the source line SL and the sidewall insulating film 126 and between the source line SL and the substrate 10. For example, the barrier film 127 includes titanium, or includes titanium and titanium nitride. In the case where the barrier film 127 is included, the source line SL is electrically connected to the substrate 10 via the barrier film 127. For example, the source line SL extends in a plate configuration in the stacking direction (the Z-direction) and the X-direction. An upper layer interconnect 80 is disposed above the source line SL (referring to FIG. 2). The upper layer interconnect 80 extends in the Y-direction. The upper layer interconnect 80 is electrically connected to the multiple source lines SL arranged along the Y-direction.

In the staircase portion 2 as shown in FIG. 4, interconnect portions 130 are provided inside the fourth insulating film 118. The interconnect portions 130 are electrically connected to the gate contact portions 123. The interconnect portions 130 are electrically connected to a not-illustrated memory peripheral circuit. The memory peripheral circuit is provided on the substrate 10. The contact portions Cb are provided inside the third insulating film 117 and the fourth insulating film 118 in the memory cell array 1.

The semiconductor device of the embodiment includes a contact portion 140a where the substrate 10 and the semiconductor body 20 are in contact. The contact portion 140a of the embodiment protrudes from the major surface 10a of the substrate 10 toward the stacked body 100. The contact portion 140a between the substrate 10 and the semiconductor body 20 is convex along the stacking direction of the stacked body 100 (the Z-direction) (e.g., referring to FIG. 6). Similarly, a contact portion 140b between the substrate 10 and the post 120 also is convex along the stacking direction of the stacked body 100 (the Z-direction) (e.g., referring to FIG. 7). A contact portion 140c between the gate contact portion 123 and the electrode layer (SGD, WL, and SGS) also is convex along the stacking direction of the stacked body 100 (the Z-direction) (e.g., referring to FIG. 8). A contact portion 140d between the substrate 10 and the source line SL also is convex along the stacking direction of the stacked body 100 (the Z-direction) (e.g., referring to FIG. 9).

A method for manufacturing the semiconductor device of the embodiment will now be described.

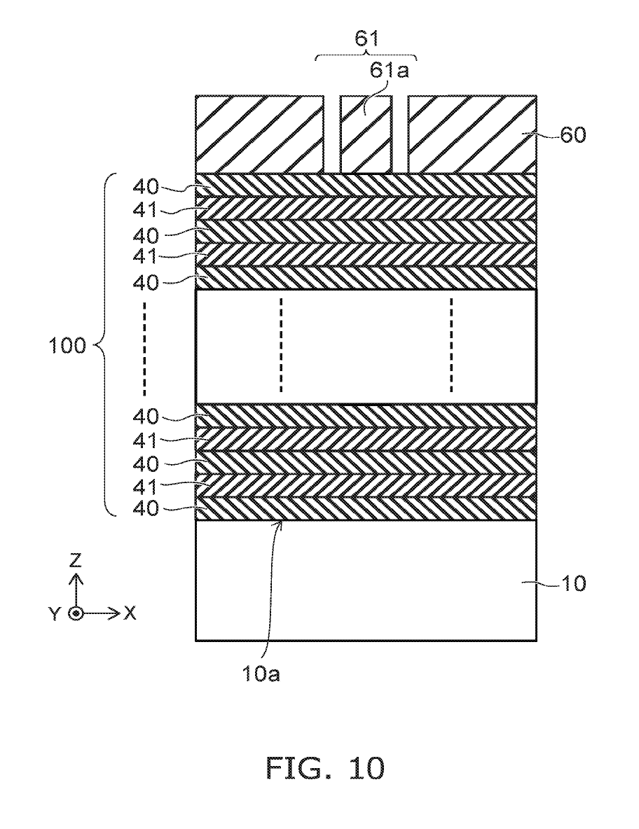

FIG. 10 to FIG. 18 are schematic cross-sectional views showing the method for manufacturing the semiconductor device of the embodiment. FIG. 10 to FIG. 18 correspond to the cross section shown in FIG. 6. FIG. 10 to FIG. 19 also show a method for manufacturing the columnar portion CL of the semiconductor device of the embodiment.

As shown in FIG. 10, the stacked body 100 is formed on the major surface 10a of the substrate 10. The stacked body 100 is formed by alternately stacking the insulating bodies 40 and replacement members 41. The insulating bodies 40 include, for example, silicon oxide. A material that has etching selectivity with the insulating bodies 40 is selected as the replacement members 41. The replacement members 41 include, for example, silicon nitride. For example, the insulating bodies 40 and the replacement members are formed using CVD. Then, a mask layer 60 is formed on the stacked body 100. Then, a hole pattern 61 is formed in the mask layer 60. In the manufacturing method, the hole pattern 61 corresponds to the pattern of the memory hole MH.

FIG. 19 is a schematic plan view of the hole pattern 61.

In the manufacturing method as shown in FIG. 19, the hole pattern 61 includes an island pattern 61a on the inner side of the hole pattern 61. For example, the hole pattern 61 and the island pattern 61a each are circular when viewed from a plane. The hole pattern 61 and the island pattern 61a are, for example, concentric circles. Thereby, the hole pattern 61 is a ring pattern.

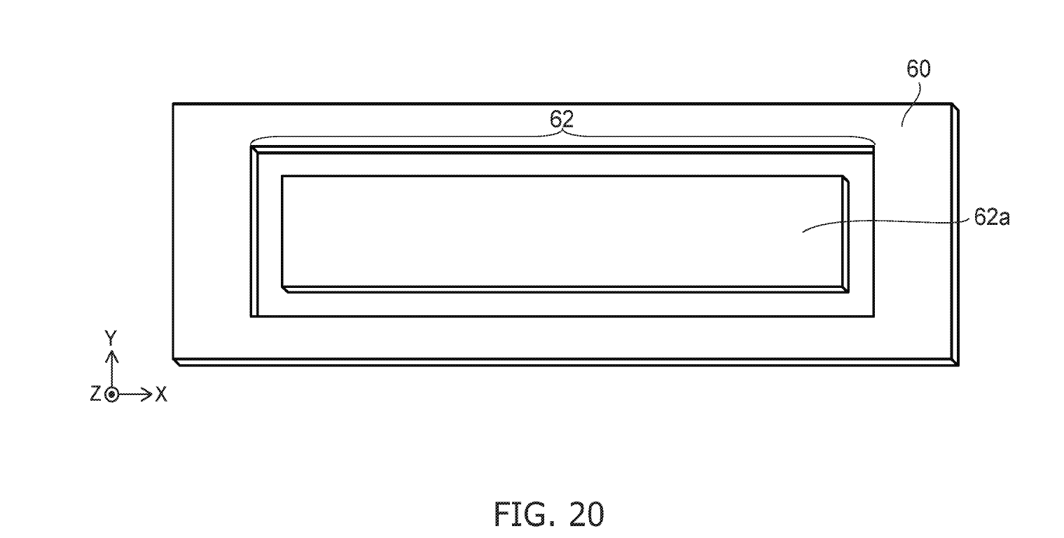

Thus, when the semiconductor device of the embodiment is manufactured, the island pattern 61a is formed on the inner side of the hole pattern 61; and the hole pattern 61 that includes the island pattern has a ring configuration when viewed from the plane. The hole pattern 61 that has the ring configuration is used not only when forming the memory hole MH but also when forming the hole HR and the contact hole CC. The slit ST has a rectangular configuration. The pattern of the slit ST is a space pattern. However, similarly to the hole pattern, the space pattern of the slit ST is closed when viewed from the plane. In other words, the slit ST has a ring configuration. Accordingly, even when forming the slit ST, it is sufficient for an island pattern 62a having a line configuration to be formed on the inner side of a space pattern 62 having a rectangular configuration as shown in FIG. 20.

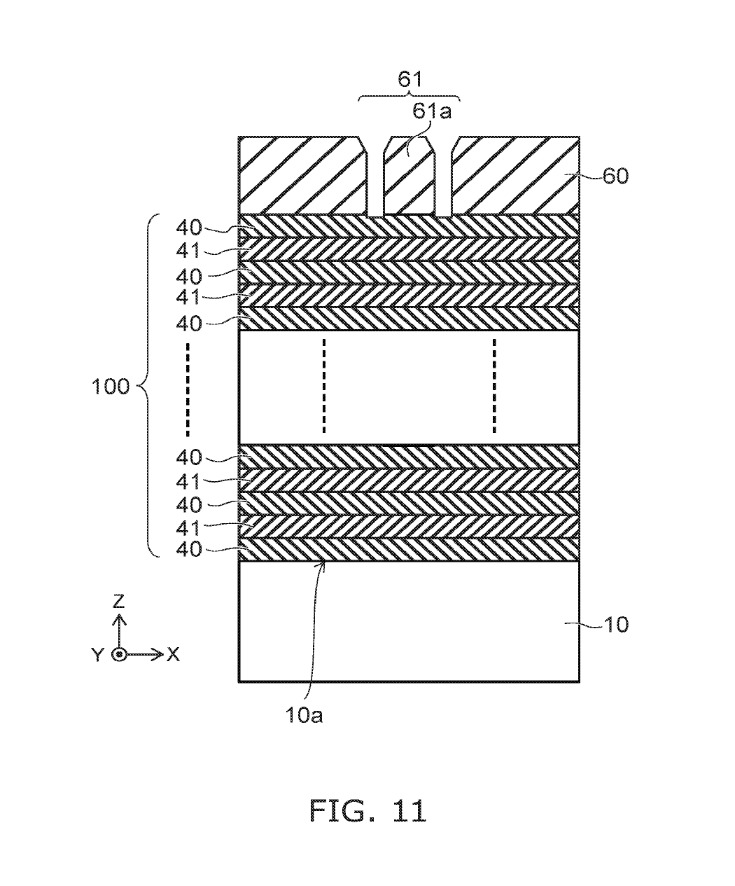

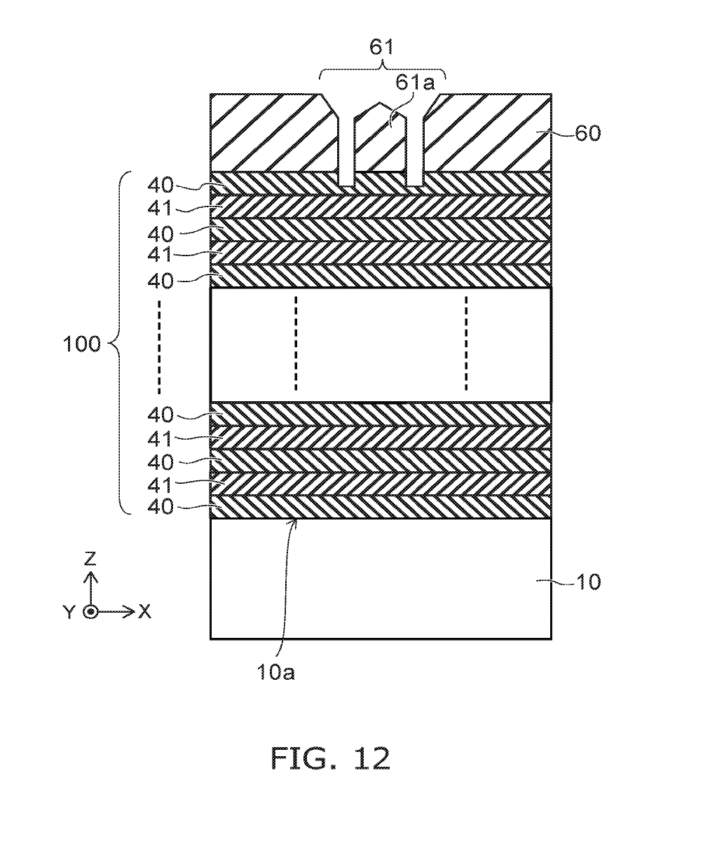

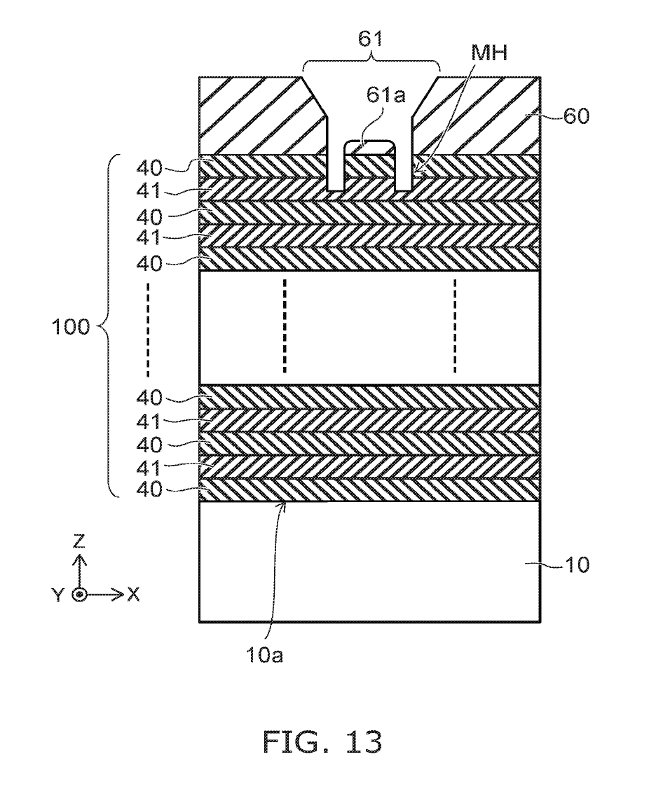

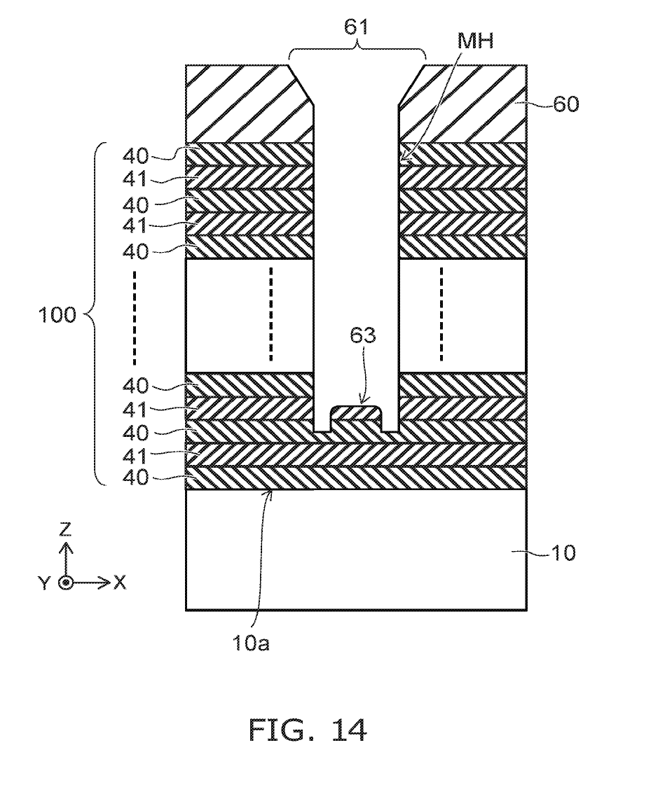

Then, the memory hole MH is formed inside the stacked body 100 by etching the stacked body 100 using the mask layer 60 at the mask of the etching. The etching is anisotropic etching. The anisotropic etching is, for example, reactive ion etching (RIE). As shown in FIG. 11, the edge of the hole pattern 61 having the ring configuration is etched in the initial stage of the anisotropic etching. As the etching progresses, the island pattern 61a on the inner side of the hole pattern 61 is etched ahead of the portion on the outer side of the hole pattern 61 as shown in FIG. 12. Therefore, as shown in FIG. 13 to FIG. 14, the etching progresses in the stacked body 100 while allowing a convex portion 63 that is formed to correspond to the island pattern 61a to remain on the inner side of the memory hole MH.

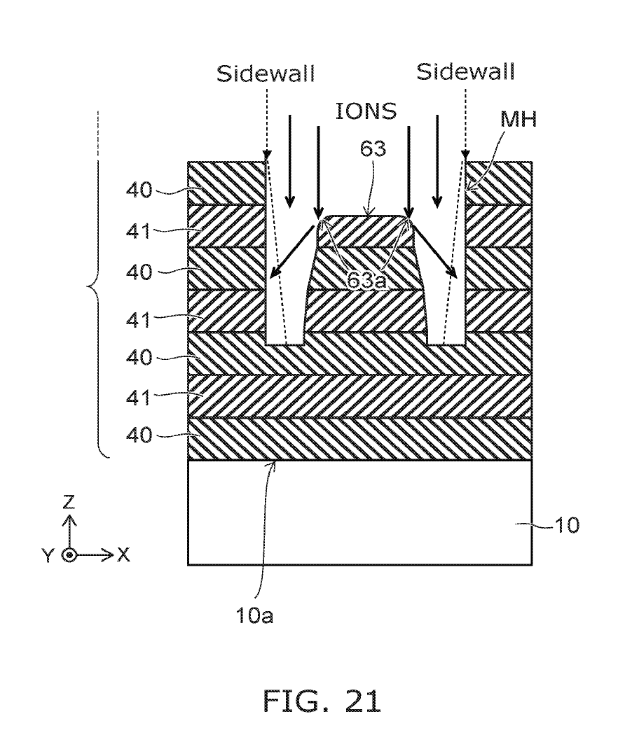

FIG. 21 is a schematic cross-sectional view showing the state of the anisotropic etching.

When anisotropic etching of the stacked body 100 is performed as shown in FIG. 21, the ions are reflected by a rounded corner 63a of the convex portion 63. The reflected ions etch the sidewall of the memory hole MH. Therefore, the sidewall of the memory hole MH that is tilted to become finer toward the lower layers is closer to being perpendicular compared to the case where the convex portion 63 is not included in the interior of the memory hole MH.

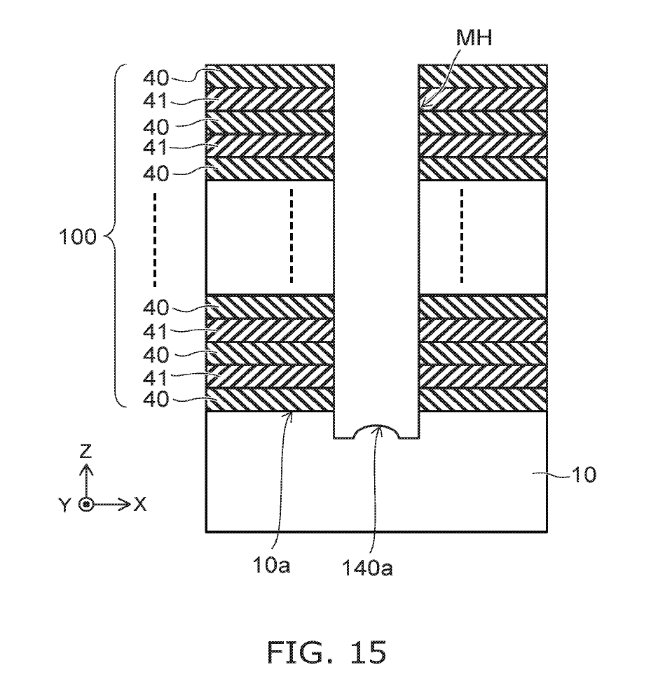

Ultimately, as shown in FIG. 15, the contact portion 140a that is convex along the stacking direction (the Z-direction) is formed in the major surface 10a of the substrate 10 exposed at the bottom of the memory hole MH.

Thus, in the manufacturing method of the embodiment, the mask layer 60 that has the hole pattern 61 having the ring configuration and including the island pattern 61a on the inner side of the hole pattern 61 is used to form the opening. In such a mask layer 60, it is sufficient to set the size of the island pattern 61a and the spacing between the hole patterns 61 to be as follows.

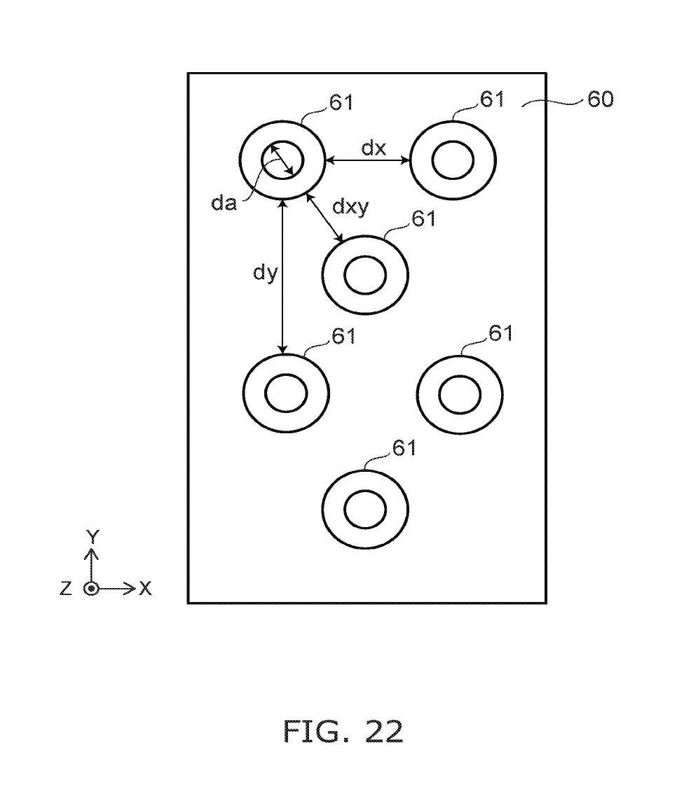

FIG. 22 is a schematic plan view showing an arrangement of the hole patterns.

As shown in FIG. 22, the spacings dX, dY, and dXY between the hole patterns 61 are set to be wider than a diameter da of the island pattern 61a. The spacing dX is the spacing between the mutually-adjacent hole patterns 61 along the X-direction. The spacing dY is the spacing between the mutually-adjacent hole patterns 61 along the Y-direction. The spacing dXY is the spacing between the mutually-adjacent hole patterns 61 along an oblique direction.

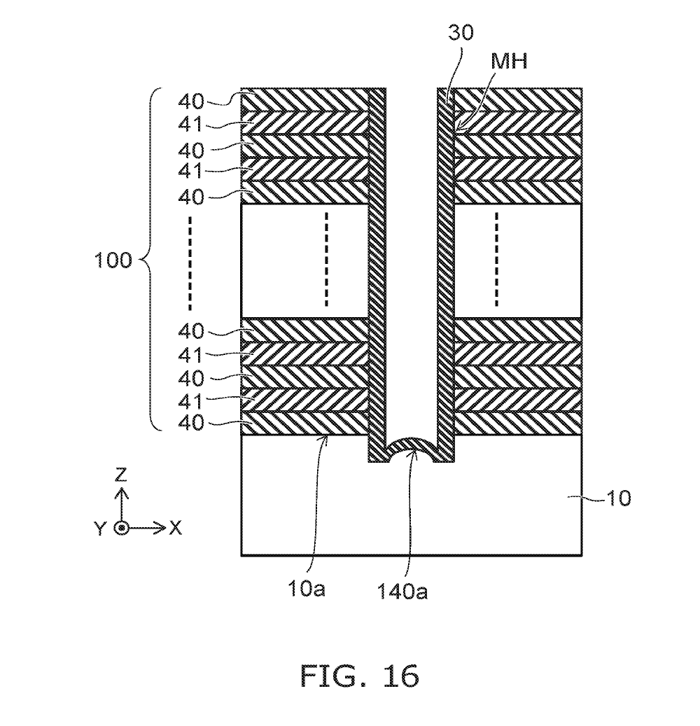

Then, as shown in FIG. 16, the memory film 30 is formed on the sidewall of the memory hole MH and on the major surface 10a exposed at the bottom of the memory hole MH. For example, the memory film 30 is formed by forming the cover insulating film 31 shown in FIG. 6 on the inner wall of the memory hole MH and on the contact portion 140a exposed at the bottom of the memory hole MH, forming the charge storage film 32 on the cover insulating film 31, and forming the tunneling insulating film 33 on the charge storage film 32.

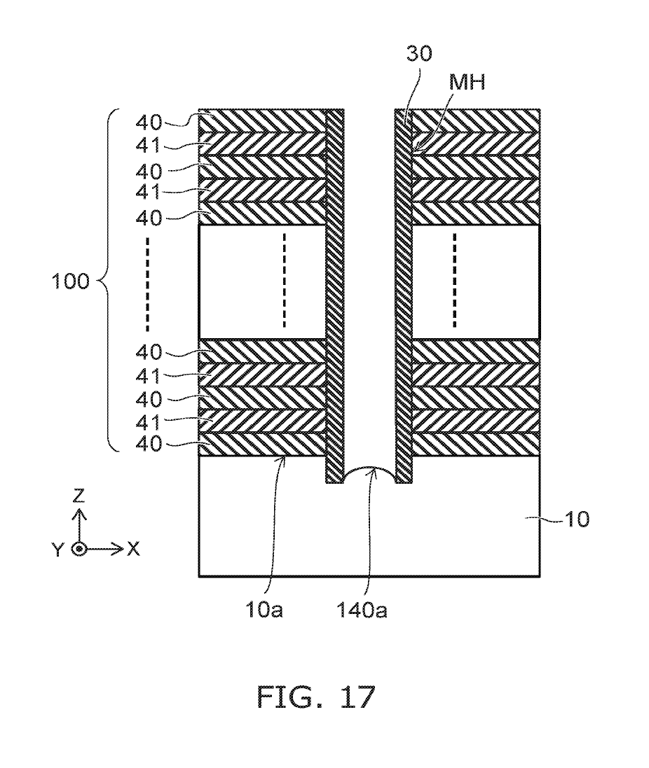

Then, as shown in FIG. 17, anisotropic etching of the memory film 30 on the contact portion 140a is performed until the contact portion 140a is exposed.

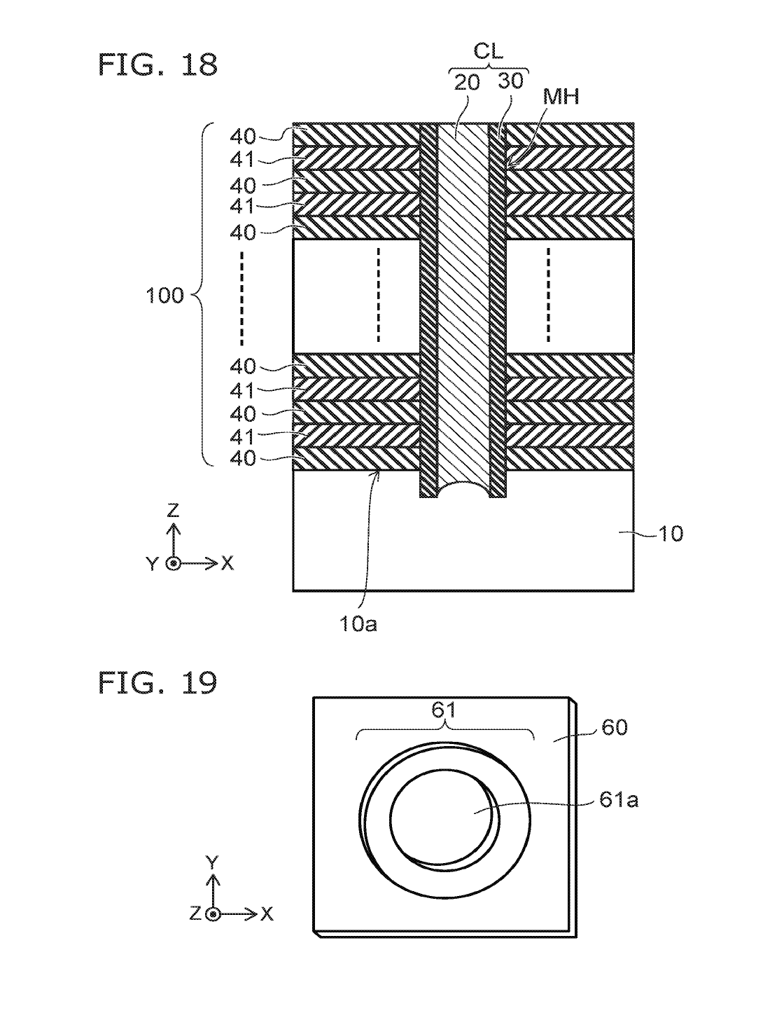

Then, as shown in FIG. 18, the semiconductor body 20 is formed in the interior of the memory hole MH. For example, the semiconductor body 20 is formed by depositing silicon on the stacked body 100 where the memory hole MH is formed. Thereby, the columnar portion CL is formed inside the stacked body 100. Then, the slit ST is formed inside the stacked body 100. The slit ST is formed in a portion not illustrated in FIG. 18. Then, the replacement members 41 are removed from the stacked body 100 via the not-illustrated slit ST. Thereby, a space is formed between the insulating body 40 and the insulating body 40.

Then, as shown in FIG. 6, for example, a conductor is filled using CVD through the space via the not-illustrated slit ST. The conductor is, for example, tungsten. Thereby, the electrode layers (SGD, WL, and SGS) are formed between the insulating body 40 and the insulating body 40.

For example, the semiconductor device of the embodiment can be manufactured by such a manufacturing method.

According to the semiconductor device of the embodiment, the openings such as the memory holes MH, etc., are formed in the stacked body 100 by using the mask layer 60 having the hole pattern 61 having the ring configuration and including the island pattern 61a on the inner side of the hole pattern 61. Therefore, a semiconductor device can be obtained in which the sidewalls of the openings are closer to being perpendicular. In the case where the sidewalls of the openings, e.g., the sidewalls of the memory holes MH, are closer to being perpendicular, the fluctuation of the resistance values of the word lines WL can be suppressed to be small. If the fluctuation of the resistance values of the word lines WL can be suppressed to be small, the fluctuation of the charge/discharge characteristics of the word lines WL also can be suppressed to be small. Accordingly, according to the embodiment, for example, a semiconductor device can be obtained in which the occurrence of misprogramming such as program disturbance, read disturbance, etc., can be suppressed.

According to the semiconductor device of the embodiment, the contact portion 140a is convex along the stacking direction (the Z-direction). Therefore, the contact surface area between the substrate 10 and the semiconductor body 20 is large compared to the case where the contact portion 140 is flat. When the contact surface area becomes large, the contact resistance between the substrate 10 and the semiconductor body 20 becomes small. If the contact resistance becomes small, for example, a larger cell current can be caused to flow from the memory string to the source line SL. For example, causing the large cell current to flow is advantageous for increasing the capacity of the memory strings (the number of the memory cells MC connected in series). This is also advantageous for further downscaling and higher integration.

In the semiconductor device of the embodiment, the contact portion 140c and the contact portion 140d also are convex along the stacking direction (the Z-direction). Therefore, the contact resistance between the gate contact portion 123 and the electrode layer (SGD, WL, and SGS) and the contact resistance between the substrate 10 and the source line SL also are small compared to the case where the contact portions are flat. The decrease of these contact resistances also is advantageous for further downscaling and higher integration.

In the semiconductor device of the embodiment, the contact portion 140b also is convex along the stacking direction (the Z-direction). Therefore, the strength of the post 120 is increased compared to the case where the contact portion is flat. The strength of the post 120 is increased also because the sidewall of the hole HR is closer to being perpendicular. The increase of the strength of the post 120 is advantageous also for increasing the number of stacks of the stacked body 100, that is, increasing the capacity of the memory strings.

Thus, according to the semiconductor device of the embodiment, a semiconductor device and a method for manufacturing the semiconductor device can be provided in which the sidewalls of the openings are closer to being perpendicular.

Embodiments are described above. However, the embodiments are not limited to the embodiments recited above; and the embodiments recited above are not the only embodiments.

For example, although the contact portions 140a to 140d each are convex in the stacking direction (the Z-direction) in the embodiments recited above, at least one of the contact portions 140a to 140d may be convex.

The information that is stored by the memory cell MC may be binary, ternary, or higher. Misprogramming such as program disturbance, read disturbance, etc., does not occur easily in the semiconductor devices of the embodiments. Therefore, applications are effective for semiconductor devices in which the information stored by the memory cell MC is ternary or higher.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a stacked body provided on a major surface of a substrate, the stacked body including a plurality of electrode layers stacked with an insulating body interposed;
a memory cell array provided inside the stacked body; and
a columnar portion provided inside the memory cell array, the columnar portion extending along a stacking direction of the stacked body, the columnar portion including a semiconductor body and a memory film, the memory film including a charge storage portion,
the substrate including a first contact portion contacting the semiconductor body, a configuration of the first contact portion being convex along the stacking direction.

2. The device according to claim 1, wherein
a configuration of the columnar portion is a columnar configuration having a concave bottom surface.

3. The device according to claim 1, further comprising
a staircase portion provided in the stacked body.

4. The device according to claim 3, further comprising
a post provided in the staircase portion, the post extending along the stacked body direction,
wherein the substrate includes a second contact portion contacting the post, and
a configuration of the second contact portion is convex along the stacking direction.

5. The device according to claim 4, wherein
the post includes an insulating body.

6. The device according to claim 4, wherein
a configuration of the post is a columnar configuration having a concave bottom surface.

7. The device according to claim 3, further comprising
a contact portion provided in the staircase portion, the contact portion extending along the stacking direction,
wherein the electrode layer includes a third contact portion contacting the contact portion, and
a configuration of the third contact portion is convex along the stacking direction.

8. The device according to claim 7, wherein
the contact portion includes a conductive body.

9. The device according to claim 7, wherein
a configuration of the contact portion is a columnar configuration having a concave bottom surface.

10. The device according to claim 2, further comprising
a plate portion provided from the memory cell array to the staircase portion, the plate portion extending along the stacking direction of the stacked body and a major surface direction of the substrate,
wherein the substrate includes a fourth contact portion contacting the plate portion, and
a configuration of the fourth contact portion is convex along the stacking direction.

11. The device according to claim 10, wherein
the plate portion includes a conductive body.

12. The device according to claim 10, wherein
a configuration of the plate portion is a plate configuration having a concave bottom surface.

13. A method for manufacturing a semiconductor device, comprising:
forming a structure body on a substrate, the structure body including an insulating body;
forming a mask layer on the structure body, the mask layer including a hole pattern, the hole pattern including an island pattern on an inner side of the hole pattern; and
forming an opening in the structure body by using the mask layer as a mask.

14. The method according to claim 13, wherein
the opening is formed by anisotropic etching of the structure body.

15. The method according to claim 13, wherein
the hole pattern including the island pattern on the inner side has a ring configuration when viewed from a plane.

16. The method according to claim 15, wherein
the hole pattern and the island pattern each are circular.

17. The method according to claim 16, wherein
the hole pattern and the island pattern are concentric circles.

18. The method according to claim 15, wherein
the hole pattern has a rectangular configuration, and the island pattern has a line configuration.

19. The method according to claim 13, wherein
the structure body includes a conductive body, and
the insulating body is stacked alternately with the conductive body.
